(19) United States
(12) Patent Application Publication
(10) Pub. No.: US 2006/0222899 A1
(43) Pub. Date: Oct. 5, 2006

(54) Magnetic recording media

(75) Inventors: Shinobu Sugimura, Yokohama-shi (JP); Masatoshi Sakurai, Tokyo (JP); Seiji Morita, Yokohama-shi (JP); Takeshi Okino, Yokohama-shi (JP)

Correspondence Address: NIXON & VANDERHYE, PC, 901 NORTH GLEBE ROAD, 11TH FLOOR, ARLINGTON, VA, 22203, US

(73) Assignee: KABUSHIKI KAISHA TOSHIBA, Tokyo (JP)

(21) Appl. No.: 11/389,530

(22) Filed: Mar. 27, 2006

(30) Foreign Application Priority Data
Mar. 30, 2005 (JP) 2005-097972

(51) Int. Cl. G11B 5/64; C23C 14/00; B05D 3/12

(52) U.S. Cl. 428/826; 204/192.15; 204/192.34; 427/127; 427/355; 428/834

(57) ABSTRACT

A magnetic recording media has a substrate and a magnetic recording layer containing ferromagnatic patterns on the substrate, the magnetic recording layer including a data zone to constitute a recording track and a servo zone to constitute a preamble region, an address region and a burst region, in which the address region and the burst region are separated by a part of the recording track.

### CROSS-REFERENCE TO RELATED APPLICATIONS

This application is based upon and claims the benefit of priority from prior Japanese Patent Application No. 2005-097972, filed Mar. 30, 2005, the entire contents of which are incorporated herein by reference.

### BACKGROUND OF THE INVENTION

1. Field of the Invention

The present invention relates to a magnetic recording media having a magnetic recording layer in which servo zones are formed using patterns of a ferromagnetic layer, a reticle for electron-beam projection lithography used to manufacture the magnetic recording media, and a method of manufacturing the magnetic recording media.

2. Description of the Related Art

There is a perpetual demand for the recording capacity for a magnetic recording media (magnetic disk) installed in a magnetic disk apparatus (hard disk drive; referred to as HDD below).

The HDD has a structure in which a doughnut-shaped magnetic disk, a head slider including a magnetic head, a head suspension assembly that supports the head slider, a voice coil motor (VCM), and a circuit board are installed in a chassis.

The magnetic disk includes a large number of tracks formed concentrically, and each of the tracks has sectors sectioned every specific angle. The magnetic disk is mounted on and rotated by a spindle motor. The magnetic head performs read and write of various digital data. Thus, the tracks in which user data is recorded are arranged in a circumferential direction, while servo marks for position control are arranged so as to cross the tracks. The servo marks include a preamble region, an address region, and a burst region. The servo marks may include a gap region in addition to these regions.

A so-called discrete track media in which recording tracks are formed using patterns of a ferromagnetic layer has been proposed as a technique for increasing the density of the magnetic disk. To manufacture the discrete track media, it is desirable to form servo zones using patterns of the ferromagnetic layer as well as data zones including the recording tracks. This is because, if one of the zones is first formed and the other is subsequently formed, the two zones cannot be easily aligned with one another, leading to a complicated process.

To form a magnetic recording layer in which data zones and servo zones are formed using patterns of a ferromagnetic layer, the following method can be efficiently used: depositing a ferromagnetic layer on a nonmagnetic substrate, applying a resist to a surface of the ferromagnetic layer, and then carrying our imprint lithography using a stamper. To produce such a stamper, a micromachining technique is required for forming protrusions and recesses in a size of 100 nm or less.

Conventionally, electron-beam direct writing is used as a method for patterning a master used for manufacturing a stamper. In contrast, studies have been made of a method comprising producing a reticle by electron-beam direct writing or photolithography and then producing a master for a stamper by projection lithography through the reticle using an electron beam stepper. This is because the latter method is expected to improve pattern accuracy.

No example has been known in which a stamper is produced by electron-beam projection lithography using a reticle and then a discrete track media is manufactured by imprint lithography using the stamper. Here, with reference to a method of manufacturing an optical recording media (Jpn. Pat. Appln. KOKAI Publication No. 2002-342986), an example of a possible method of manufacturing a discrete track media using the electron-beam projection lithography technique will be described below.

First, a reticle having enlarged patterns n-times as large as patterns on a desired magnetic disk is produced using an electron-beam direct writing technique. A resist is applied to a wafer (master) for producing a stamper. The resist is subjected to electron-beam projection lithography through the resultant reticle using an electron beam stepper. Desired fine patterns formed by projecting the enlarged patterns in a reduced manner to one n-th are written on the resist applied to the wafer. The resist is developed to produce a resist master having protrusions and recesses on the surface thereof. A plating seed layer is deposited by sputtering on the surface of the resist master on which the protrusions and recesses are formed, and then an electroformed layer is deposited by electroforming. The electroformed layer and the plating seed layer are stripped off from the resist master. Then, the electroformed layer with the plating seed layer is subjected to cleaning, rear-surface polishing, and punching to produce a stamper.

On the other hand, a ferromagnetic layer is deposited on a glass substrate. A resist is applied to the surface of the ferromagnetic layer. The protrusions and recesses of the stamper are transferred to the resist by imprinting. Resist residues at the bottoms of the recesses in the resist are removes by reactive ion etching (referred to as RIE below) so as to expose the ferromagnetic layer. The exposed parts of the ferromagnetic layer are etched by ion milling to form patterns of the ferromagnetic layer. Finally, the resist remaining on the patterns of the ferromagnetic layer are removed to manufacture discrete track media.

Two types of reticles, a stencil mask and a membrane mask, are used for the electron-beam projection lithography. The characteristics of these masks will be described in brief.

In the stencil mask, the areas except the written pattern layer are made penetrated portions. During the electron-beam projection lithography, electron beams are transmitted through the penetrated portions while being scattered by the pattern layer, which constitutes a non-penetrated portion. An image which reflects the patterns on the stencil mask can thus be formed. With the stencil mask, electron beams are transmitted through the penetrated portions, so that neither low scattering nor chromatic aberration occurs.

The membrane mask includes a membrane layer of a light element such as silicon or silicon nitride which allows electron beams to pass through-easily and a pattern layer of a heavy metal element such as chromium or tungsten which scatters electron beams formed on the membrane layer. Electron beams are transmitted through the membrane layer, so that the percentage for which non-scattered electros account is smaller than in the case of the stencil mask. Further, most electrons having their angles changed by elastic scattering do not pass through the aperture, and some of the electrons passing through the aperture to contribute to writing lose energy through non-elastic scattering. This easily causes increase in energy dispersion of electrons and reduction in resolution, i.e., chromatic aberration.

For the above reticles, the pattern layer of the stencil mask is about 2 μm in thickness and the pattern layer of the membrane mask is thinner. Accordingly, both reticles have very low mechanical strength. With these thin reticles, if area ratios of patterns differ markedly between two adjacent regions, stress easily concentrates on the boundary region between the two regions. Consequently, deformation such as distortion or pattern loss is likely to occur on the boundary region.

When a reticle with deformation or pattern loss is used to produce a stamper by electron-beam projection lithography and the resultant stamper is used to manufacture a discrete track media by imprint lithography, pattern defects may occur in the discrete track media. These factors make it difficult to provide a discrete track media with good signal characteristics.

### BRIEF SUMMARY OF THE INVENTION

A magnetic recording media according to an aspect of the present invention comprises: a substrate and a magnetic recording layer containing ferromagnatic patterns on the substrate, the magnetic recording layer including a data zone to constitute a recording track and a servo zone to constitute a preamble region, an address region and a burst region, wherein the address region and the burst region are separated by a part of the recording track.

A reticle for electron-beam projection lithography according to another aspect of the present invention comprises enlarged patterns corresponding to the patterns of the ferromagnetic layer on the above magnetic recording media.

A method of manufacturing a magnetic recording media according to still another aspect of the present invention comprises: producing a reticle for electron-beam projection lithography comprising enlarged patterns corresponding to the patterns of the ferromagnetic layer on the above magnetic recording media; applying a resist to a master and carrying out electron-beam projection lithography by using the reticle to transfer the enlarged patterns to the resist in a reduced manner to produce a resist master; carrying out electroforming using the resist master to produce a stamper; and depositing a ferromagnetic layer on a nonmagnetic substrate, applying a resist to a surface of the ferromagnetic layer, and carrying out imprint lithography using the stamper to manufacture the above magnetic recording media.

### BRIEF DESCRIPTION OF THE SEVERAL VIEWS OF THE DRAWING

FIG. 1 is a plan view of a discrete track media according to an embodiment of the present invention;

FIG. 2 is a plan view showing a magnetic recording layer in a discrete track media having servo zones similar to those in a conventional magnetic disk;

FIG. 3 is a schematic diagram generally showing a state that a region with high-density patterns is formed adjacent to a region with low-density patterns;

FIG. 4 is a plan view showing a magnetic recording layer in a discrete track media according to an embodiment of the present invention;

FIG. 5 is a plan view of a reticle having patterns corresponding to FIG. 2 and stress that may occur in the reticle;

FIG. 6 is a plan view of a reticle having patterns corresponding to FIG. 4 and stress that may occur in the reticle;

FIGS. 7A, 7B, 7C, 7D, 7E, 7F and 7G are sectional views showing a method of manufacturing a stencil mask according to an embodiment of the present invention;

FIGS. 8A and 8B are diagrams illustrating dispersion of track pitches and line undulation of the patterns in a reticle and dispersion of track pitches and line undulation of the patterns which are transferred in a reduced manner; and

FIG. 9 is a perspective view of a magnetic disk apparatus according to an embodiment of the present invention.

### DETAILED DESCRIPTION OF THE INVENTION

Embodiments of the present invention will be described with reference to the drawings.

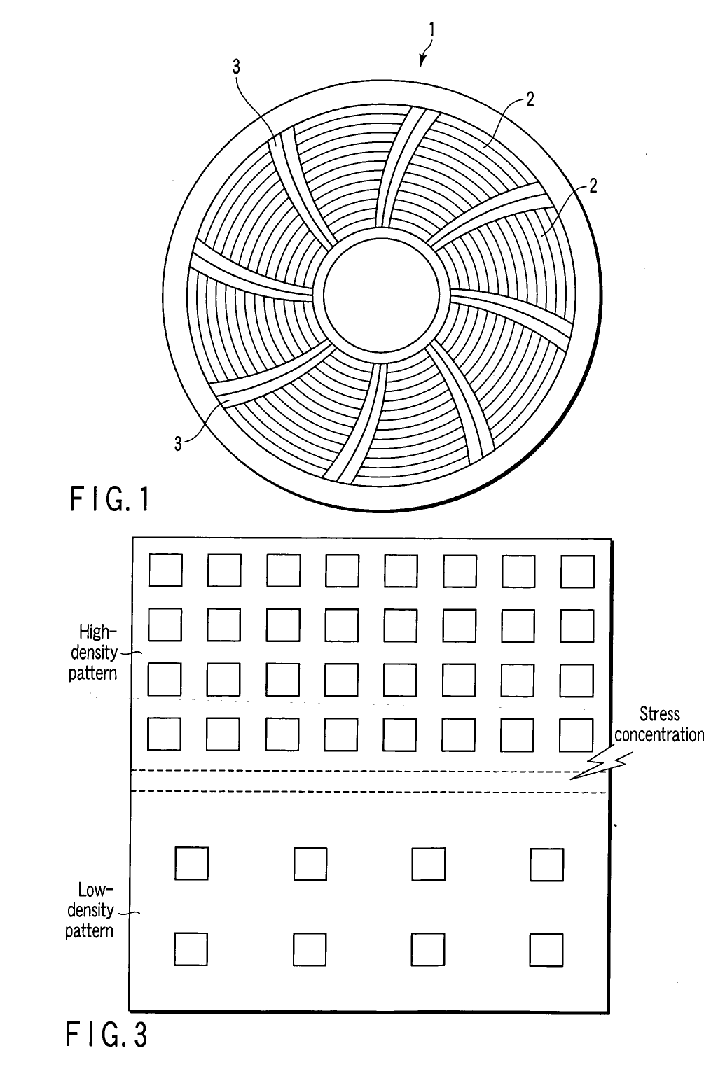

FIG. 1 shows a plan view of a discrete track media according to an embodiment of the present invention. As shown in FIG. 1, the discrete track media 1 includes data zones 2 including patterns of a ferromagnetic layer separated by grooves substantially concentric circles and servo zones 3 formed approximately circular arcs in the radial direction so as to divide the data zones 2. User data is recorded in recording tracks in the data zones 2. Positional data is read out by a magnetic head from the servo zones 3. The area of the servo zones 3 is set at most one tenth of that of the data zones 2 in order to ensure a higher recording density of HDD.

FIG. 2 is a plan view showing a magnetic recording layer in a discrete track media having servo zones similar to those in a conventional magnetic disk. The data zone 2 includes recording tracks 21. The servo zone 3 includes a preamble region 31, an address region 32, and a burst region 33. In the discrete track media, the recording tracks 21, the preamble region 31, the address region 32, and the burst region 33 are formed using patterns of a ferromagnetic layer in a form of protrusions. The spaces between the patterns of a ferromagnetic layer are often filled with a nonmagnetic material. When the servo zone 3 is designed in the same manner as that in the conventional magnetic disk, the preamble region 31, the address region 32, and the burst region 33 are formed adjacent and continuous to one another.

The area ratios of the patterned nonmagnetic portion in respective regions are: about 33% for the data zone 2 (recording tracks 21); about 50% for the preamble region 31; about 50% for the address region 32; and about 25% for the burst region 33.

If a reticle is used to produce a stamper by electron-beam projection lithography and the stamper is then used to manufacture a discrete track media by imprint lithography, the area ratios of regions in the pattern layer on the reticle is also as described above.

FIG. 3 is a schematic diagram generally showing a state that a region with high-density patterns is formed adjacent to a region with low-density patterns. If the area ratios of patterns thus differ markedly between two adjacent regions, stress easily concentrates on the boundary region between the two regions. Consequently, deformation such as distortion or pattern loss is likely to occur on the boundary region. For example, in the case shown in FIG. 2, the area ratios of patterns vary most significantly between the address region 32 and the burst region 33, which are 50% and 25%. Thus, stress concentrates most on the boundary region between the two regions, which likely lead to deformation such as distortion or pattern loss on that region. A similar phenomenon occurs in other boundary regions. When a reticle with deformation or pattern loss is used to produce a stamper by electron-beam projection lithography and the resultant stamper is used to manufacture a discrete track media by imprint lithography, the signal characteristics of the discrete track media may be degraded.

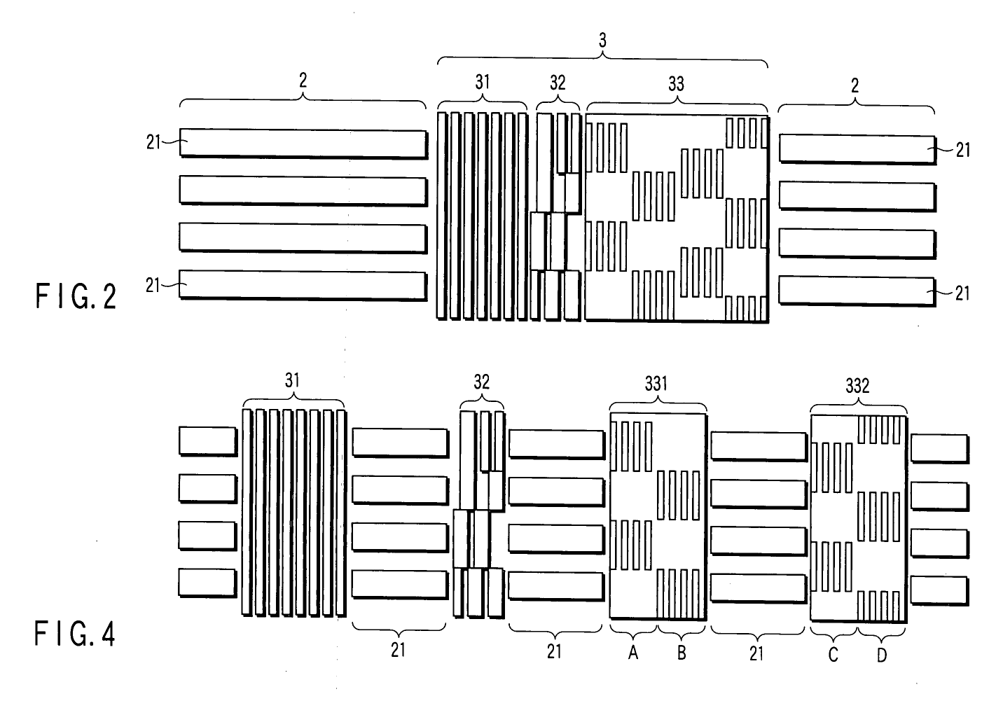

Therefore, in a discrete track media according to an embodiment of the present invention, at least the address region and the burst region are separated by a part of the recording tracks. Moreover, in another embodiment of the present invention, the preamble region and address region may be separated by a part of the recording tracks, or the AB burst region and the CD burst region may be separated by a part of the recording tracks. In this case, in the AB burst region, regions each including patterns of the same phase are defined as the A burst region and the B burst region. By way of example, in FIG. 4, the A burst region is denoted by A, and the B burst region is denoted by B. However, the order of A and B burst regions is not indispensable, and the reverse order may be used. Also, in the CD burst region, regions each including patterns of the same phase are defined as the C burst region and the D burst region. By way of example, in FIG. 4, the C burst region is denoted by C, and the D burst region is denoted by D. However, the order of C and D burst regions is not indispensable, and the reverse order may be used.

FIG. 4 is a plan view showing a magnetic recording layer in a discrete track media according to an embodiment of the present invention. In FIG. 4, parts of the recording tracks are sandwiched between the preamble region 31 and address region 32, between the address region 32 and AB burst region 331, and between the AB burst region 331 and CD burst region 332, respectively, by which above adjacent two regions in the servo zone 3 are separated from each other.

A reticle for electron-beam projection lithography according to an embodiment of the present invention has enlarged patterns corresponding to FIG. 4. Thus, the two adjacent regions in the servo zone 3 are separated by a part of the recording tracks 21. This reduces the stress concentration on the boundary areas in the servo zone 3, making it possible to disperse the stress all over the reticle.

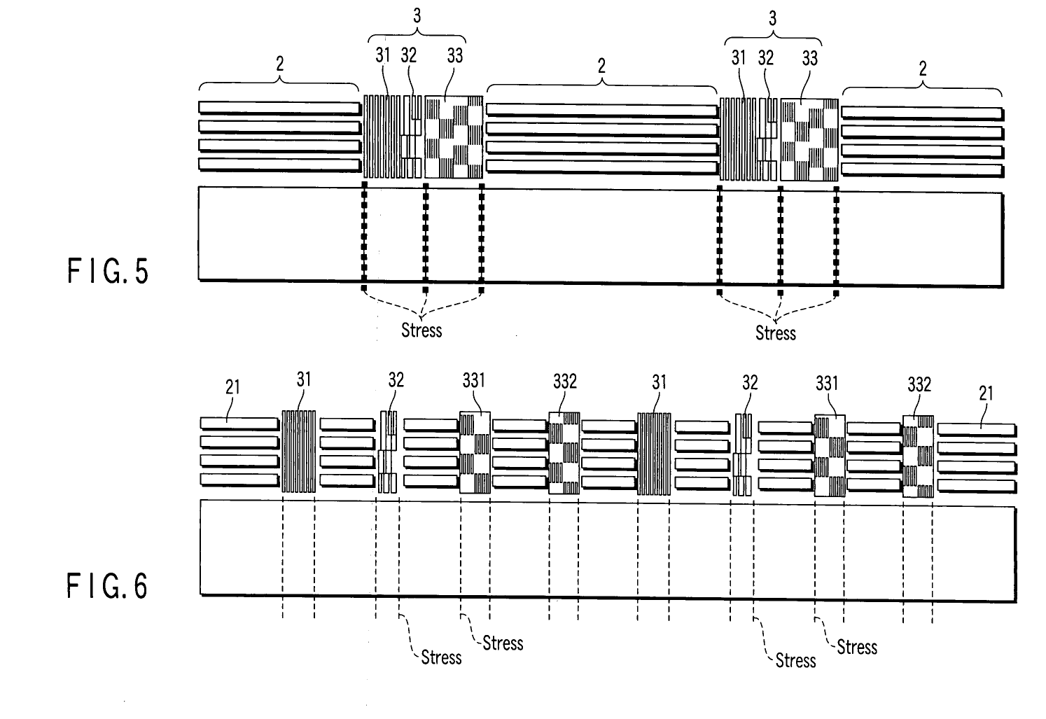

FIG. 5 is a plan view of a reticle having patterns corresponding to FIG. 2, showing stresses (depicted by broken lines) that may occur in the reticle. FIG. 6 is a plan view of a reticle having patterns corresponding to FIG. 4, showing stresses (depicted by broken line) that may occur in the reticle. In FIGS. 5 and 6, the magnitude of stress is represented by the thickness of the broken lines. By separating the regions in the servo zone as shown in FIG. 6, it is possible to disperse the stress all over the reticle. Consequently, a good reticle which is free from distortion or pattern loss can be produced.

When a reticle free from deformation or pattern loss is used to produce a stamper by electron-beam projection lithography and the resultant stamper is used to manufacture a discrete track media by imprint lithography, pattern defects are prevented from occurring in the discrete track media. In addition, since the area ratios of patterns differ insignificantly between two adjacent regions, flying of the magnetic head over the media can be made stable. It is thus possible to provide-a high-performance discrete track media with which read clock extraction error rate, address error rate, noise, and track pitch error are reduced.

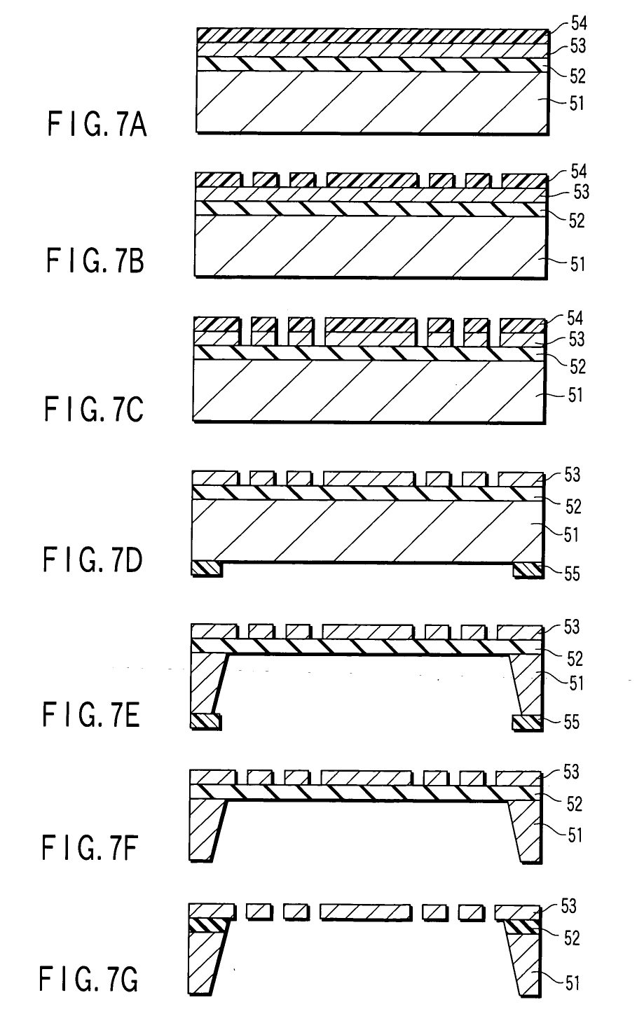

Now, with reference to FIGS. 7A, 7B, 7C, 7D, 7E, 7F and 7G, a method of manufacturing a stencil mask according to an embodiment of the present invention will be described.

A silicon oxide film 52 serving as an etching stopper is formed on a silicon substrate 51. An SOI (silicon on insulator) layer 53 is formed on the silicon oxide film 52. A resist (available from ZEON Corporation under the trade name of ZEP-520) is diluted 1.5 times with anisole, followed by filtering with a 0.2-μm membrane filter, to prepare a resist solution. The resist solution is spin-coated on the SOI layer 53, which is then prebaked at 200° C. for three minutes, to form a resist 54 with a thickness of 0.3 μm (FIG. 7A).

The silicon substrate 51 is set to an electron-beam direct writing apparatus, conveyed to a predetermined position using a conveying system, and then subjected to electron-beam direct writing in a vacuum to form enlarged patterns four times as large as patterns on the desired discrete track media. During the writing, the writing apparatus is controlled so that the preamble region, address region, and burst region in the servo zone are separated from each other by a part of the recording tracks, as shown in FIG. 4. The 4× enlarged patterns provide the writing apparatus with a large process margin, thus enabling more accurate writing than fine patterns on the same scale.

The silicon substrate 51 is immersed in a developer (available from ZEON Corporation under the trade name of ZED-N50) for 90 seconds to develop resist patterns 54, and then immersed in a rinse liquid (available from ZEON Corporation under the trade name of ZMD-B) for 90 seconds for rinsing, and then dried in an air blow (FIG. 7B). The SOI layer 53 is subjected to anisotropic etching using the resist patterns 54 as a mask until the silicon oxide film 52 is exposed (FIG. 7C). After the unnecessary resist is removed, a resist is applied to the rear surface of the silicon substrate 51, and then resist patterns 55 are formed by lithography (FIG. 7D). The rear surface of the silicon substrate 51 is etched with KOH until the silicon oxide film 52 is exposed (FIG. 7E). The unnecessary resist is removed (FIG. 7F). Further, the silicon oxide film 52 is removed using fluoric acid to provide a stencil mask free from distortion or defects (FIG. 7G).

Now, a method of manufacturing a stamper according to an embodiment of the present invention will be described.

A resist (available from ZEON Corporation under the trade name of ZEP-520) is diluted 1.5 times with anisole, followed by filtering with a 0.2-μm membrane filter, to prepare a resist solution. The resist solution is spin-coated on a silicon master, which is then prebaked at 200° C. for three minutes, to form a resist with a thickness of 0.1 μm.

The silicon master is set to an electron-beam projection lithography apparatus, and then subjected to ¼ electron-beam projection lithography through the stencil mask, manufactured as above, to produce a resist master to which the enlarged patterns on the stencil mask are transferred in a reduced manner. The resist master is immersed in a developer (available from ZEON Corporation under the trade name of ZED-N50) for 90 seconds to develop resist patterns, and then immersed in a rinse liquid (available from ZEON Corporation under the trade name of ZMD-B) for 90 seconds for rinsing, and then dried in an air blow.

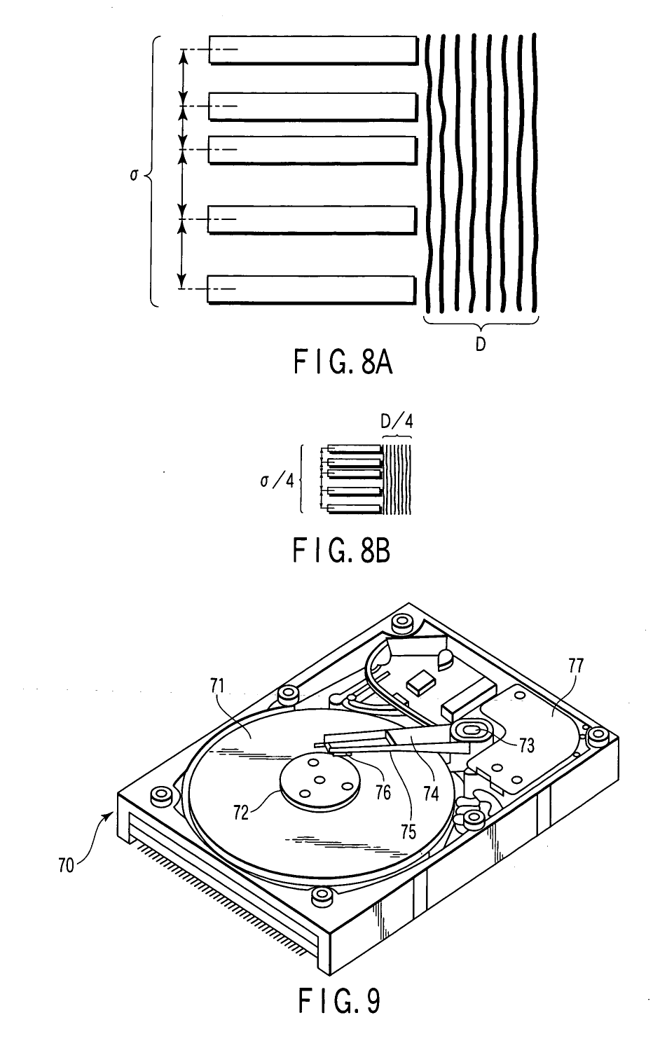

At this stage, even if the 4× enlarged patterns in the reticle involve dispersion of track pitches (standard deviation of which is a) or line undulation in the preamble region (with a distance D) as shown in FIG. 8A, the transferred patterns in a ¼-reduced manner reduces the dispersion of the track pitches to σ/4 and the line undulation to D/4. Since the 4× enlarged patterns enable accurate writing as described above and also the reduced transfer enables to reduce the disorder of the patterns, the method according to an embodiment of the present invention enables to form very accurate patterns.

A conductive film serving as a plating seed layer is formed on the resist master by sputtering. For example, pure nickel is used as a target, the chamber is evacuated to 8×10⁻³ Pa, an argon gas is introduced into the chamber to adjust the pressure to 1 Pa, and then sputtering is carried out for 40 seconds under a power of 400 W to form a conductive film with a thickness of 30 nm.

A nickel film is electroformed on the conductive film formed on the resist master using nickel sulfamate plating solution (available from Showa Chemical Corporation under the trade name of NS-160), for 75 minutes. Electroforming conditions are, for example, as follows:

nickel sulfamate: 600 g/L,

boric acid: 40 g/L,

surfactant (sodium laurylate): 0.15 g/L,

solution temperature: 55° C.,

pH: 4.0, and

current density: 20 A/dm².

The electroformed film has a thickness of about 300 μm. The electroformed film and the conductive film are stripped off from the resist master. Resist residues are removed by oxygen plasma ashing. The oxygen plasma ashing is carried out for 10 minutes with introducing 100 sccm of oxygen gas into the chamber and applying a power of 100 W. A father stamper including the conductive film and the electroformed film is thus obtained. Unnecessary part of the resultant father stamper is punched off using a metal blade to produce an imprint stamper.

Now, a method of manufacturing a discrete track media according to an embodiment of the present invention will be described.

The stamper is ultrasonically cleaned with acetone for 15 minutes. A solution is prepared by diluting fluoroalkylsilane [CF₃(CF₂)₇CH₂CH₂Si(OMe)₃] (available from GE Toshiba Silicone corporation under the trade name of TSL8233) with ethanol to 5%. The solution is used to improve releasability in imprinting. The stamper is immersed in the solution for 30 minutes. The solution is blown off by a blower. Then, the stamper is annealed at 120° C. for 1 hour.

On the other hand, a perpendicular recording film is formed on a 0.85-inch doughnut-shaped glass substrate to be processed. A novolac-based resist (available from Rohm and Haas Company under the trade name of S1801) is spin-coated on the perpendicular recording film at a rotation speed of 3,800 rpm. The stamper is pressed against the resist at 2,000 bar for one minute to transfer the patterns on the stamper to the resist. The resist film is irradiated with ultraviolet rays for five minutes, and the annealed at 160° C. for 30 minutes.

The imprinted substrate is placed in an ICP (inductively coupled plasma) etching apparatus. Oxygen RIE is carried out under a pressure of 2 mTorr and Ar ion milling is subsequently carried out to etch the perpendicular recording film. Oxygen RIE is carried out at 400 W and 1 Torr to strip the etching mask. CVD (chemical vapor deposition) is carried out to deposit DLC (diamond-like carbon) with a thickness of about 3 nm as a protective film. A lubricant is applied to the protective film to a thickness of about 1 nm by dipping. A discrete track media according to an embodiment of the present invention is thus manufactured.

FIG. 9 shows a perspective view of a magnetic disk apparatus (HDD) to which the discrete track media is installed. As shown in FIG. 9, in a chassis 70, a doughnut-shaped magnetic disk 71 is rotatably mounted on a spindle motor 72. An actuator arm 74 is attached to a pivot 73 located near the magnetic disk 71. A suspension 75 is attached to the tip of the actuator arm 74. A head slider 76 is supported on the bottom surface of the suspension 75. A voice coil motor (VCM) 77 is provided at the other end of the actuator arm 74. The voice coil motor 77 is used to move the actuator arm 74 while rotating the magnetic disk 71, to allow the magnetic head-71, provided at the tip of the head slider 76, to fly over a desired track. The magnetic head 71 is thus positioned to carry out read and write. Signals are processed by a circuit board installed in the bottom of the chassis.

Evaluation of signals is carried out for a HDD in which the discrete track media according to an embodiment of the present invention is installed. Then, good signal characteristics are obtained. The reason is as follows. The stamper is produced by electron-beam projection lithography using the reticle in which the two adjacent regions in the servo zone are separated by a part of the recording tracks. Then, the discrete track media is manufactured by imprint lithography, using the resultant stamper. As a result, pattern defects are avoided and the magnetic head flies stably over the media. This made it possible to reduce the reproduction clock extraction error rate, address error rate, noise, and track pitch error.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A magnetic recording media comprising:
a substrate and a magnetic recording layer containing ferromagnatic patterns on the substrate, the magnetic recording layer including a data zone to constitute a recording track and a servo zone to constitute a preamble region, an address region and a burst region,
wherein the address region and the burst region are separated by a part of the recording track.

2. The magnetic recording media according to claim 1, wherein the preamble region and the address region are separated by a part of the recording track.

3. The magnetic recording media according to claim 1, wherein the burst region includes A, B, C and D burst regions, and the A and B burst regions and the C and D burst regions are separated by a part of the recording track.

4. The magnetic recording media according to claim 1, further comprising a nonmagnetic material filled in a space between the ferromagnatic patterns.

5. A reticle for electron-beam projection lithography comprising enlarged patterns corresponding to the patterns of the ferromagnetic layer on the magnetic recording media according to claim 1.

6. A method of manufacturing a magnetic recording media, comprising:
producing a reticle for electron-beam projection lithography comprising enlarged patterns corresponding to the patterns of the ferromagnetic layer on the magnetic recording media according to claim 1;
applying a resist to a master and carrying out electron-beam projection lithography by using the reticle to transfer the enlarged patterns to the resist in a reduced manner to produce a resist master;
carrying out electroforming using the resist master to produce a stamper; and
depositing a ferromagnetic layer on a nonmagnetic substrate, applying a resist to a surface of the ferromagnetic layer, and carrying out imprint lithography using the stamper to manufacture the magnetic recording media according to claim 1.
